(19) United States
(12) Patent Application Publication
(10) Pub. No.: US 2026/0057129 A1
(43) Pub. Date: Feb. 26, 2026

(54) INVERSE LINKAGE SYNTHESIS

(71) Applicants: International Business Machines Corporation, Armonk, NY (US); Massachusetts Institute of Technology, Cambridge, MA (US)

(72) Inventors: Akash Srivastava, Boston, MA (US); Faez Ahmed, Winchester, MA (US); Amin Heyrani Nobari, Cambridge, MA (US)

(21) Appl. No.: 18/811,716

(22) Filed: Aug. 21, 2024

(51) Int. Cl. G06F 30/17; G06F 30/27

(52) U.S. Cl. CPC G06F 30/17; G06F 30/27

(57) ABSTRACT

A dataset of linkage mechanisms is obtained and an input representation of a given target curve is received. The dataset is searched to identify one or more linkage mechanisms of the dataset that approximate the input representation using computational techniques. The one or more identified linkage mechanisms are refined based on a global optimization algorithm and modifications are applied to the one or more refined linkage mechanisms using a butterfly extension. The one or more modified linkage mechanisms are presented as one or more digital three-dimensional models, respectively.

### BACKGROUND

The present invention relates generally to the electrical, electronic and computer arts and, more particularly, to computer-aided mechanical design and machine learning for mechanical design.

### BRIEF SUMMARY

Principles of the invention provide techniques for inverse linkage synthesis. In one aspect, an exemplary method includes the operations of obtaining a dataset of linkage mechanisms; receiving an input representation of the given target curve; searching the dataset to identify one or more linkage mechanisms of the dataset that approximate the input representation using computational techniques; refining the one or more identified linkage mechanisms based on a global optimization algorithm; applying modifications to the one or more refined linkage mechanisms using a butterfly extension; and presenting the one or more modified linkage mechanisms as one or more digital three-dimensional models, respectively.

In one aspect, a computer program product comprises one or more tangible computer-readable storage media and program instructions stored on at least one of the one or more tangible computer-readable storage media, the program instructions executable by a processor, the program instructions comprising obtaining a dataset of linkage mechanisms; receiving an input representation of the given target curve; searching the dataset to identify one or more linkage mechanisms of the dataset that approximate the input representation using computational techniques; refining the one or more identified linkage mechanisms based on a global optimization algorithm; applying modifications to the one or more refined linkage mechanisms using a butterfly extension; and presenting the one or more modified linkage mechanisms as one or more digital three-dimensional models, respectively.

In one aspect, an apparatus comprises a memory and at least one processor, coupled to the memory, and operative to perform operations comprising obtaining a dataset of linkage mechanisms; receiving an input representation of the given target curve; searching the dataset to identify one or more linkage mechanisms of the dataset that approximate the input representation using computational techniques; refining the one or more identified linkage mechanisms based on a global optimization algorithm; applying modifications to the one or more refined linkage mechanisms using a butterfly extension; and presenting the one or more modified linkage mechanisms as one or more digital three-dimensional models, respectively.

As used herein, “facilitating” an action includes performing the action, making the action easier, helping to carry the action out, or causing the action to be performed. Thus, by way of example and not limitation, instructions executing on a processor might facilitate an action carried out by instructions executing on a remote processor, by sending appropriate data or commands to cause or aid the action to be performed. Where an actor facilitates an action by other than performing the action, the action is nevertheless performed by some entity or combination of entities.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates the evolution of an example mechanical linkage system;

FIG. 2 illustrates the evolution of a linkage mechanism during generation, in accordance with an example embodiment;

FIG. 3 illustrates a linkage mechanism undergoing simulation, in accordance with an example embodiment;

FIG. 4 is a flowchart for an example position generator method, in accordance with an example embodiment;

FIG. 5 shows example training data for training the contrastive learning model, in accordance with an example embodiment;

FIG. 6 shows two example target curves and corresponding candidate curves, in accordance with an example embodiment;

FIGS. 7-10 illustrate a heuristic optimization for generating a mechanical linkage, in accordance with an example embodiment;

FIG. 11 is a flowchart for an example method for generating a mechanical linkage, in accordance with an example embodiment;

FIG. 12 illustrates a workflow for simulating a candidate linkage mechanism, in accordance with example embodiments;

FIGS. 13-14 show a comparison of results of example embodiments with results of example state-of-the-art methods; and

FIG. 15 depicts a computing environment according to an embodiment of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

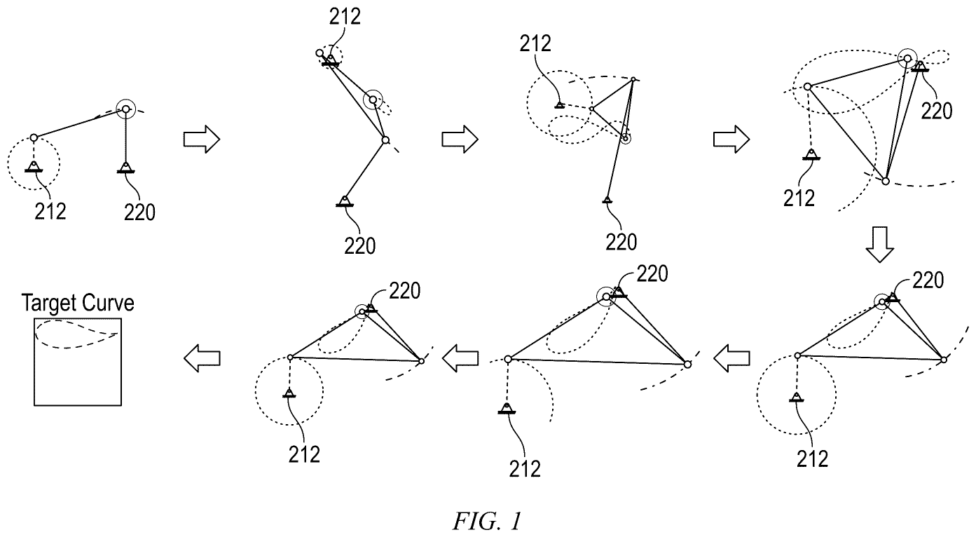

FIG. 1 illustrates the evolution of an example mechanical linkage system. As illustrated in FIG. 1, a driving motor 212 manipulates the mechanical linkage system via an actuator arm (represented by a dashed linkage). The target joint (circled in FIG. 1) is tasked with tracing the target curve. Anchored joints are attached to an anchor mechanism (such as anchor mechanism 220). Mechanical linkage systems are used in many applications, including simulating/designing cranes, bicycles, robotics, engines, and the like. For example, mechanical linkage systems are used in suspension systems or engines for automobiles, shifter-to-gear box linkage mechanisms, linkages that enable robotic devices to walk or run, industrial cranes, toys, and the like. Despite this, the design of complex kinematic systems is not well understood and typically requires trial and error, expert knowledge, and/or heuristics to identify good designs. As the complexity of the task increases, the manual iterative process of mechanical design has proven to be the biggest bottleneck. A viable alternative to the forward, optimization driven manual process is to explore a learning-based inverse design approach. In such an approach, a statistical model that maps from the space of the target curves to the space of the linkage mechanisms is employed. One hypothesis is that given enough training data, a suitably designed deep generative model should be able to accomplish this mapping. However, in an environment with a lack of large-scale datasets of linkage mechanisms and their corresponding curves, this inverse design approach would be infeasible. Moreover, conventional simulators for simulating such mechanical linkage systems are relatively accurate, but are generally slow and inefficient.

By improving the efficiency of mechanical linkage system simulation, example embodiments generate and curate an extremely large dataset of both positive and negative (locking) samples of linkage systems. This dataset is then used to perform inverse design, identifying linkage systems that will trace a desired shape. One example method can also be applied to other inverse design problems of similar form.

In one example embodiment, a system synthesizes a large, diverse dataset of linkage mechanisms and target curve pairings. Further, utilizing an exemplary dataset generation mechanism, one or more embodiments can synthesize linkage mechanisms that can handle target curves that require mechanisms that are a factor of two to three more complicated than those of state-of-the-art methods.

While an exemplary linkage dataset in accordance with one or more embodiments directly enables better data-driven designs by providing a large and diverse training dataset, it can also help improve numerical atlas based approaches and/or optimization based approaches by enabling a search over a larger space and providing candidates for smart initialization of optimization methods.

One or more embodiments include mechanisms with a significantly higher number of joints and providing an atlas of 1.1 billion coupler paths.

Using an exemplary linkage dataset as described herein, one or more embodiments achieves improvements by introducing candidates that are close to the desired goal by a numerical atlas-type look up for initializing optimization.

One or more embodiments enhance machine learning for mechanical design by looking at a much larger array of mechanisms and/or by not limiting the search algorithm to a specific kind of problem.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
an order of magnitude improvement in speed (reduced processing time) for performing mechanical linkage design;
an order of magnitude improvement in the accuracy of a mechanical linkage designed to trace a target curve; and
a mechanical linkage design process that is extendable to similar problems in mechanical engineering and other design tasks.

In one example embodiment, a new operator, referred to as the J-operator herein, allows the generation of feasible mechanisms with a single degree of freedom (1-DOF). A linkage mechanism dataset, referred to as the linkage dataset herein, was generated with 100 million mechanisms and 1.1 billion coupler curves. A vectorized and parallelized forward solver, 800 times faster than a nonvectorized solver, was also utilized. It is shown that 62% of the coupler curves are circular and arc-shaped, revealing a large bias in the dataset. The dataset is filtered to reduce this bias and a curated subset of 600 million coupler curves was identified.

A case study of mechanism retrieval by implementing a shape similarity-based search on the linkage dataset is demonstrated and it is shown that it yields accurate and diverse results, showing the efficacy of the dataset. Genetic algorithms are used on retrieved mechanisms to improve the results by identifying partial matches and optimizing for them. A differentiable solver and gradient-based optimization is then used to fine-tune the final mechanism and bring it closer to the desired match. If necessary, a butterfly modification is applied to the candidate mechanism to give it an additional eight degrees of freedom, which allows for further refinement of the output path.

### Generative Scheme

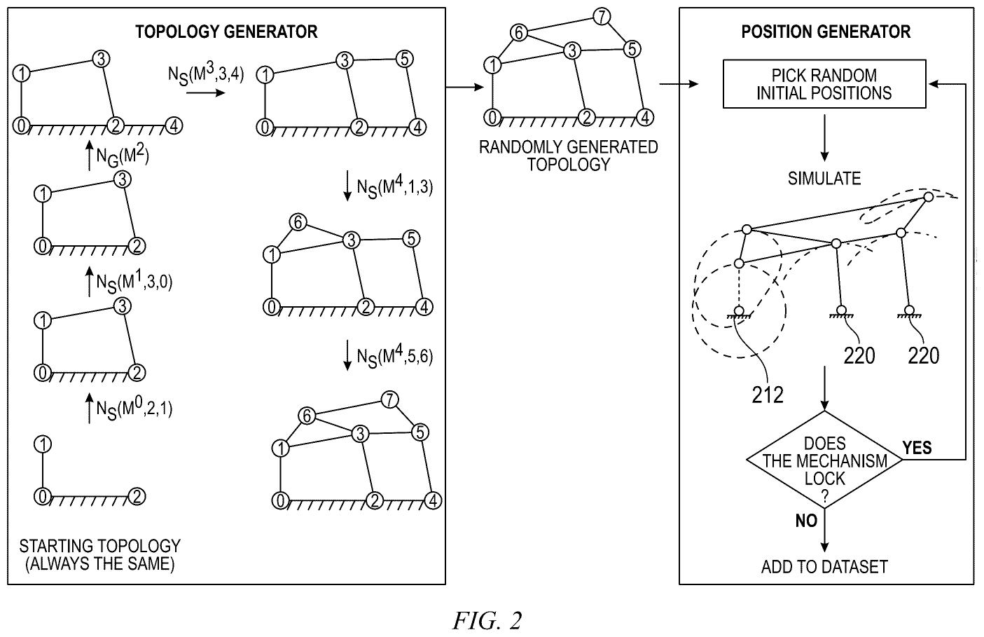

FIG. 2 illustrates the evolution of a linkage mechanism during generation, in accordance with an example embodiment. Links are randomly added to a starting topology to generate a randomly generated topology. Once generated, random initial positions are selected and a simulation is conducted. During the simulation, checks are performed to determine if the mechanism locks; that is, that the mechanism prevents the actuator arm from completing a revolution. If the mechanism locks, the candidate mechanism is discarded; otherwise, the generated topology is added to the dataset. In one example embodiment, a dataset of 100 million planar linkage mechanisms is created with 8-20 nodes resulting in over 1 billion different coupler curves.

The resulting linkage dataset is a dataset of 100 million 1-DOF (one degree of freedom) planar linkage mechanisms and 1.1 billion coupler curves, which is more than 1000 times larger than any existing database of planar mechanisms and is not limited to specific kinds of mechanisms, such as four-bars, six-bars, and the like, which are typically what most databases include. The linkage dataset is made up of various components including 100 million mechanisms, the simulation data for each mechanism, normalized paths generated by each mechanism, a curated set of paths, the code used to generate the data and simulate mechanisms, and a live web demo for interactive design of linkage mechanisms. The curated paths are provided as a measure for removing biases in the paths generated by mechanisms that enable a more even design space representation. To be able to generate such a large dataset, the J operator was introduced to generate 1-DOF mechanism topologies. Furthermore, steps are taken to speed up slow simulations of mechanisms by vectorizing the exemplary simulations and parallelizing the exemplary simulator on a large number of threads, which leads to a simulation 800 times faster than the simple simulation algorithm. This is appropriate in one or more embodiments given that, on average, 1 out of 500 candidates that are generated are valid (and all must typically be simulated to determine their validity), which means billions of simulations must typically be performed for the generation of the linkage dataset. The analysis and synthesis of the kinematics of different mechanisms are among the longest-standing problems in engineering design, capturing the attention of many scientists and engineers throughout history.

Producing very large datasets for kinematic design is a challenging problem due to the typical need for an appropriate representation scheme that does not waste resources in creating infeasible designs, and the large computation time required in simulating the movement of all linkages and ensuring diversity in the dataset. To address these gaps, the linkage dataset is introduced as a dataset of 100 million, one degree of freedom (1-DOF) planar linkage mechanisms with complexity going up to 20 linkage joints. The linkage dataset is created with a primary focus on the “Path Generation” problem. The path generation problem is the task of designing linkage mechanisms that generate a particular path described by a finite series of point coordinates. The dataset is made up of a large number of mechanisms and the simulated coupler paths traced by each joint of the mechanisms. However, it can be extended easily to other types of problems such as “Function Generation” and “Motion Generation.”

An exemplary system includes an efficient generation scheme that allows for randomly sampling valid mechanisms. To do this, a new operator is used that is guaranteed to create valid, non-degenerate, and non-locking mechanisms without any redundancies. An efficient forward simulation algorithm, which is both vectorized and parallelized, enables the simulation of mechanisms on a multi-core system in half a second, compared to the 454 seconds needed by a single thread non-vectorized solver.

Another challenge faced in generating a dataset of linkages and associated coupler paths is the extreme skewness in the types of shapes obtained from all the coupler paths. It has been observed that two types of shapes, circles and arcs, make up 62% of the paths traced. These two shapes are less interesting from the perspective of inverse kinematic synthesis (as theoretical solutions for such shapes are easily obtained). To address this issue, these shapes are detected and filtered, which leads to two datasets, namely, one raw dataset with all the generated mechanical linkages and one curated subset of paths, which randomly removes 99.5% of these two shapes and associated mechanisms.

Since the focus of the exemplary linkage dataset is on “path generation,” the exemplary linkage dataset is built such that there are no redundancies, meaning that mechanisms in the exemplary linkage dataset are guaranteed to be 1-DOF and have the mobility of one at the same time.

### J Operator

FIG. 2 (left side) illustrates the application of the joint (J) operator in the evolution of a linkage mechanism during generation, in accordance with an example embodiment. Rather than focusing on the linkages for operations, operations are applied on two existing joints. The generation begins with the initialization of the linkage mechanism with the simplest possible 1-DOF mechanism—a single actuator including a ground joint and a linkage (the actuator arm). Two existing joints within any given mechanism are then selected and a new joint that has linkages connecting it to the two selected linkages is added.

Assuming the initial mechanism has mobility of 1 (i.e., m=1), adding two linkages to the system means adding 2 to n in the mobility equation; however, the operation also adds 3 j₁ pairs (i.e., the added joint and the two other joints which just received two new connections), which essentially retains the mobility of the initial mechanism. Furthermore, since mobility is maintained in this manner, so long as the initial mechanism has no redundant linkages and constraints, the resulting mechanisms will also have no redundancies either (since mobility is maintained). In this regard, an operation is denoted as N(M^{t}; i; j) , where M^{t} is the current mechanism at iteration t starting at t=0 with the stated initial configuration and i, j≤t+3 refers to the index of the nodes in the mechanism, to which the operator is applied.

### Ensuring Simple Kinematic Loops

The exemplary J operator also ensures that the resultant mechanism always has simple kinematic loops. The J operator is a dyadic operator, where every operation of the J operator creates a simple kinematic loop between the new joint and the two existing joints. Therefore, as long as the initial mechanism consists only of simple kinematic loops, any resulting mechanism will also have only simple kinematic loops. This is useful for the exemplary simulations, as graphical solvers are used which typically require simple kinematic loops. The exemplary J operator can be used in systems with more degrees of freedom as well, and retains the mobility of the existing mechanism. Additionally, this approach can easily be extended to 3D linkage systems (with universal joints) as well with the operator now operating on three joints to maintain the original mobility.

Initialization

The above described initialization of the sequential generator is a pertinent aspect of the process. The mechanism used at the start of the sequential generator will be the simplest possible 1-DOF mechanism—a single actuator including a ground joint and a linkage, which is the actuator arm. Besides the actuator arm, an exemplary initialization mechanism also includes a floating ground joint which is fixed in space. This point is used as a starting point, because this is the simplest possible 1-DOF mechanism and, therefore, any generated mechanism from this point on will not be biased by an initial mechanism, as no simpler mechanism is possible and future mechanisms will only be generated based on the order by which the operator is applied.

When generating a large dataset, once a topology is generated using the exemplary dyadic operator, many candidates of initial positions typically have to be evaluated to find joint positions which do not lead to locking mechanisms. Furthermore, for each mechanism topology, many candidates are typically needed to capture the output space for any given topology. This means that the same mechanism topology will typically have to be simulated thousands of times. Re-initializing the solver every time and finding the path to the solution is not efficient. This issue can advantageously be overcome in the present embodiments by using the following approach. Once the path to the solution is known, this path is employed to solve different variations of the same topology without any more neighborhood searches. This avoidance of neighborhood searches significantly improves the speed of simulations compared to performing searches for every candidate.

### Simulator Optimization

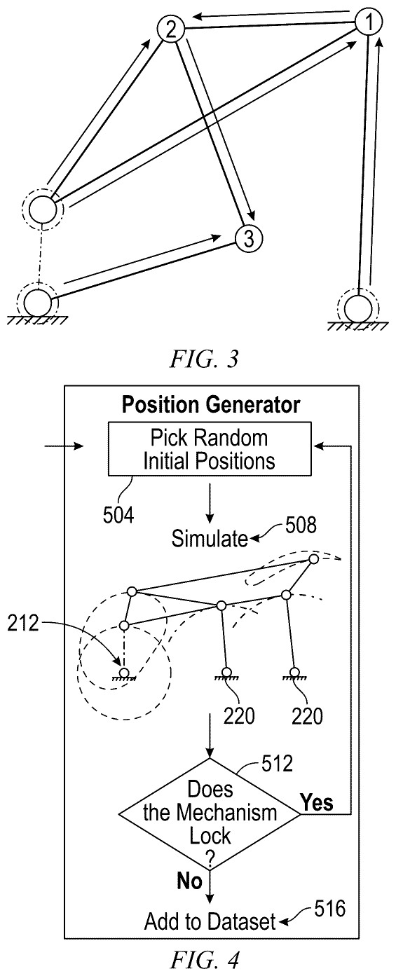

FIG. 3 illustrates a linkage mechanism undergoing simulation, in accordance with an example embodiment. (In one example embodiment, a conventional solver is utilized for the simulation.) When generating a large dataset, once a topology is generated, many candidates of initial positions have to be evaluated to find joint positions which do not lead to locking mechanisms. Furthermore, for each mechanism topology, many candidates are typically needed to capture the output space for any given topology. This means that the same mechanism topology will typically have to be simulated thousands of times.

To accomplish this, once the path to the solution is known, this path is employed to solve different variations of the same topology without any more neighborhood searches. This significantly improves the speed of simulations compared to performing searches for every candidate. This also allows gradient-based optimization.

In one example embodiment, the solver starts with the known joints (i.e., fixed and actuated joints). At every step, nodes with two known neighbors can be found. In the mechanism illustrated in FIG. 3, the path to the solution has three steps. The numbers of the joints indicate the order in which the solution is found, and the arrows indicate which two neighboring joints are needed to solve the given joint. Known nodes are highlighted with a dashed circle.

### Mechanism Representation

Mechanism topologies are modeled as undirected graphs, in which each joint (regardless of type) is considered a “node” and each linkage is considered an “edge.” Each of the nodes will have features that include its type (such as fixed, simple, actuated and the like) and its initial position. Each graph is represented by an n×n adjacency matrix A, whose (i, j) entry is zero if nodes i and j are not connected and one if they are connected.

Each mechanism is also represented by a feature matrix which, in an exemplary representation, is an n×3 matrix. Each row of this matrix includes the features of each node. The first element of each row indicates the type of the node (i.e., 1 for simple node, 0 for fixed node, and 2 for actuated nodes), and the two other elements in each row are set to be the initial positions of the nodes at time zero (which can be used to determine the length of the linkages between the joints).

### Sequences

Linkage systems can also be represented in a sequential format. This is valuable for training neural network models, such as transformers. Either graph-based or sequence-based representations can provide a unified approach for representing all kinds of kinematic systems with different types of components and relations.

### Dataset Generation

FIG. 4 is a flowchart for an example position generator method, in accordance with an example embodiment. As described above, once generated, random initial positions are selected (operation 504) and a simulation is conducted (operation 508). During the simulation, checks are performed to determine if the mechanism locks (decision block 512). If the mechanism locks, operation 504 is repeated and new random positions are selected; otherwise, the generated topology is added to the dataset (operation 516). In one example embodiment, a simulation is ended when it is determined that the mechanism does not lock; for example, when the mechanism does not lock after one revolution of the actuator arm (driving motor).

In dataset generation, a random sampling is initially started with and non-locking initial conditions are identified. A number of challenges exist, however:

scale of infeasibilities: for every 500 simulations, only ˜1 will be non-locking; use low-fidelity simulations to detect infeasibilities, cutting the cost of each evaluation by 4× (improvements in scaling and efficiency are detailed below);
computational cost of simulations: vectorize simulations and parallelize simulations; and
imbalance: the paths created by all the mechanisms tend to be biased heavily towards two specific kinds of shapes: arcs and circles.

The latter is inefficient for path generation problems. Thus, 99.5% of arcs and circles in the curated dataset are removed. 62% of the paths, if not curated, would fall under the category of circles and arcs (circles make up 34% and arcs 28%), which shows the pertinence of this step.

### Dataset Generation Method Details

In one or more embodiments, the number of nodes in any mechanism topology will be sampled from a uniform distribution ranging from 8 to 20 nodes. Start with the actuator arm as the initial linkage. Once the number of joints, n, is selected, the generated mechanism shall not be reducible to a mechanism with fewer joints. Thus, the kinematics of the mechanism topologies that are generated will rely on solving the positions of all nodes, and the final joint (in the solution path) will not be determined without all other joints having been solved (i.e., the solution path of the graphical solver to the final joint must go through all joints). This allows for uniform coverage of the design space for mechanisms with 8-20 nodes.

One or more embodiments impose the rule that the final joint in the solution path shall not be connected to any fixed joint. This rule is imposed to prevent complex mechanisms with high numbers of joints from producing simple paths, such as arcs. Because a focus of example embodiments is on generating mechanisms with path synthesis in mind, having a complex mechanism that ends up producing arcs is not desirable.

### Dataset Details

The generated linkage dataset includes 100 million different mechanisms. These mechanisms are described by the adjacency matrix of the graph describing the topology of the mechanism, and an n×3 matrix describing the initial positions and types of the mechanism joints. The assumption in these mechanisms is that the actuated arm is the arm connecting joints 0 (the initial fixed joint) and 1 (the initial simple actuated joint). The size of these mechanisms in the dataset is between 8 joints and 20 joints.

For each of the 100 million mechanisms in the dataset, the kinematics of the mechanisms are simulated for 200 equally spaced positions over the full rotation of the actuator arm. All the produced paths are normalized and the index of mechanism and joints associated with each path are stored (raw normalized paths). A dataset that is the same as the normalized dataset, but with 99.5% of circles and arcs removed, is also generated (curated normalized paths). Negative samples include those of the 100 million mechanisms that are in a locking configuration (i.e., initial positions).

### Generative Optimization Approach

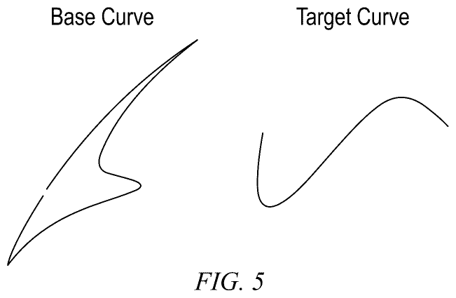

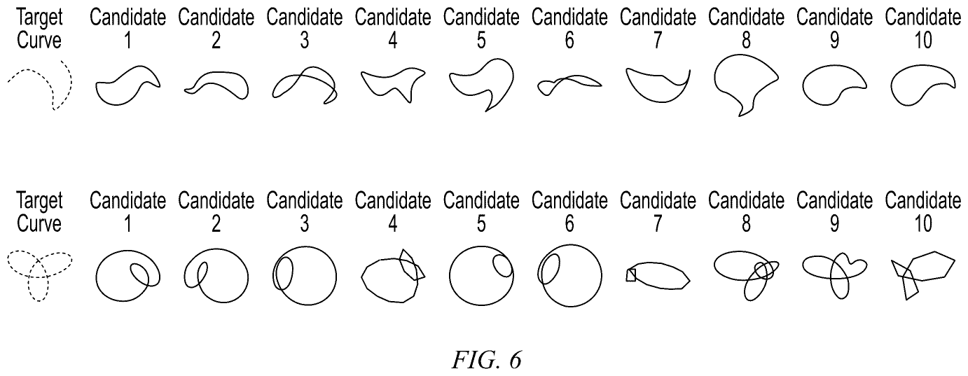

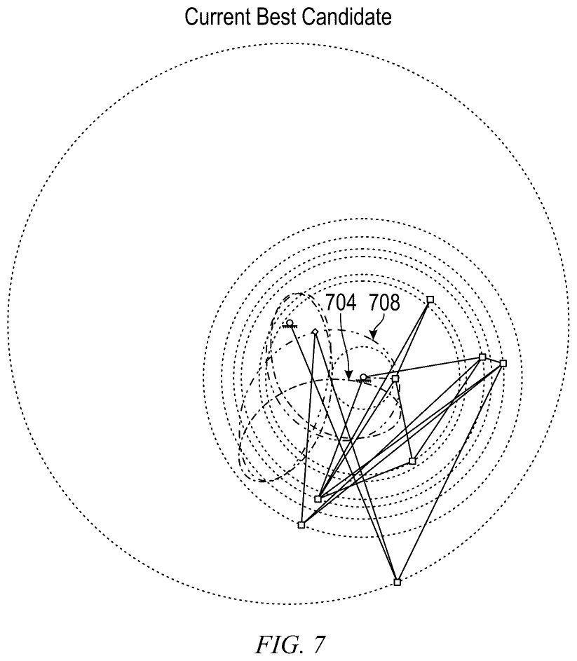

In one example embodiment, a large dataset, such as the linkage dataset, is used to train a contrastive learning model that is a machine learning model. FIG. 5 shows example training data for training the contrastive learning model, in accordance with an example embodiment. In the contrastive learning approach, the contrastive learning model is trained with a curve generated by a simulation of a given mechanism and a curve which is a rotated, truncated and/or scaled version of the former curve. The latter curve may also be a partial match of the curve generated by the given mechanism. The trained contrastive model learns to identify that the two training curves are similar and, once trained, is used to perform a fast dataset lookup and to identify close matches for any drawn or input target curves. This is done very quickly as the model can see the mechanisms in the dataset prior to look up so they do not need to be recomputed. FIG. 6 shows two example target curves and corresponding candidate curves, in accordance with an example embodiment. Each target curve is input to the trained contrastive model. In response, the trained contrastive model identifies one or more candidate curves that are similar to the input target curve. In one example embodiment, an initial match is identified and the actuator is replaced with a 4-bar rocker. A conventional non-dominated sorting genetic algorithm is then performed on the revised mechanism.

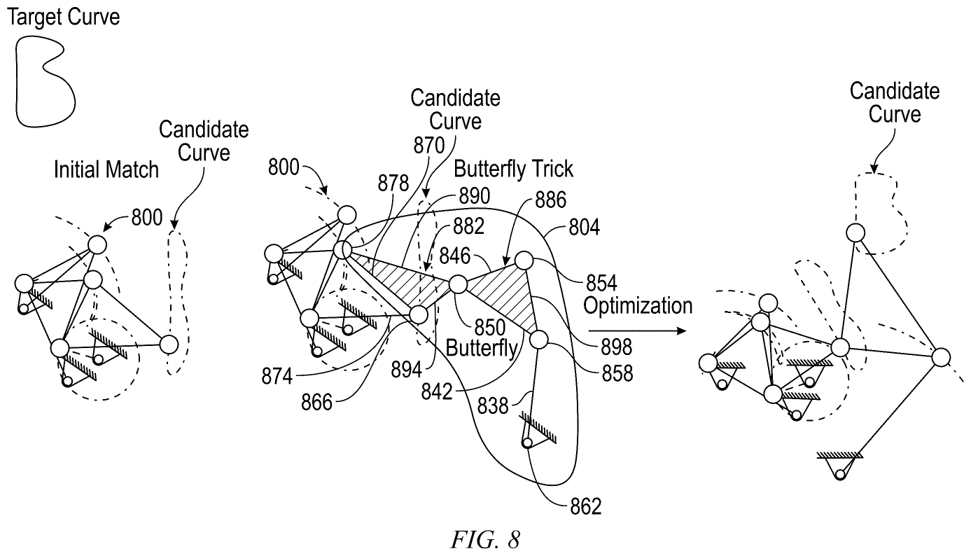

FIGS. 7-10 illustrate a heuristic optimization for generating a mechanical linkage, in accordance with an example embodiment. In one example embodiment, as illustrated in FIG. 7, the best candidates from the search are used to initialize an optimization using a genetic algorithm (GA) which further narrows down the solution. As illustrated in FIG. 7, the dashed, non-circular lines compare the target curve 704 and the curve 708 of the current best candidate. As illustrated in FIG. 8, when the gradient based optimization fails to get close enough (as indicated, for example, by finding a local minimum where the gradient is zero), a “butterfly” extension 804 is applied to the best candidate 800 to add 8 degrees of freedom (4 new joints 850, 854, 858, 862 and the corresponding linkages 838, 842, 846, 890, 894, 898 in 2D) to enable further refinement (see labeled curves in FIG. 8). As used herein, a “butterfly” extension 804 is a set of joints 850, 854, 858, 862 and linkages 838, 842, 846, 890, 894, 898, in the general shape of a butterfly, attached to the existing mechanical linkage 800. Note that 870 and its joints 866, 878 help form the butterfly but are part of the original candidate linkage 800. One of the two linkages 870, 874 connected to the output joint 866 (the most complex joint) of the existing mechanical linkage 800 is selected as an attachment point for the butterfly extension 804. The selected linkage (such as linkage 870) and two corresponding joints 866, 878 of the existing mechanical linkage 800 serve as an outside edge of a first wing 882 of the butterfly extension 804.

A new joint 850, which serves as the “body” of the “butterfly,” is connected via two new linkages 890, 894 to the two joints 866, 878 of the selected linkage 870 to complete the shape of the first wing 882. Two new joints 854, 858 are connected to each other by a new linkage 898 and each of the two new joints 854, 858 are connected to the “body” joint 850 via two new linkages 842, 846. A fourth new joint 862 is connected to one of joint 854 and joint 858 via new linkage 838. Note second butterfly wing 886. Note further that joint 862 is added in the exemplary embodiment so that the mechanism will not have a DOF of 2 (i.e., 2 degrees of freedom) and therefore not be solvable; the fourth new joint 862 and new linkage 838 keep the butterfly extension from floating in space and being unsolvable.

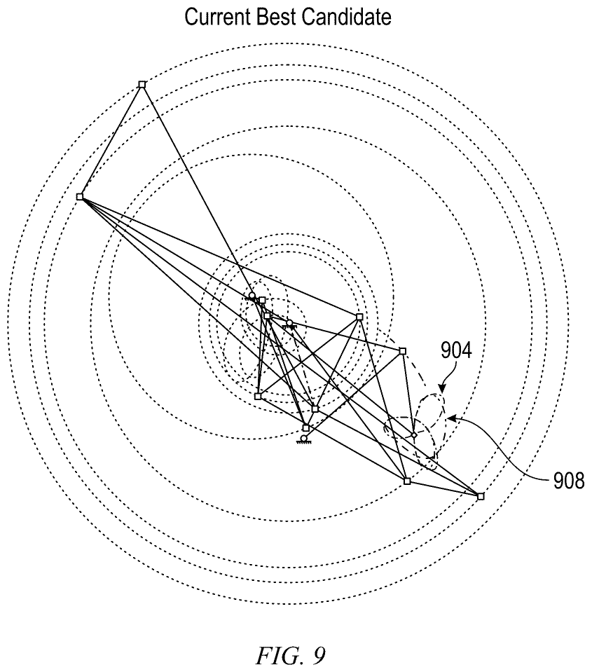

There are other ways of adding four joints to a mechanism. The butterfly extension 804 is one way that allows for kinematic adaptation. Other ways of adding four joints would edit the entire original mechanism 800 and it is hard to see it as an extension. The butterfly extension 804 only uses the linkage 870, 874 that is relevant to the output motion. In one example embodiment, the additional joints 850, 854, 858, 862 of the butterfly extension 804 are randomly selected within a given unit bounding box. If a resulting linkage mechanism is invalid (such as if it is a locking mechanism), another butterfly extension 804 with different randomly selected joints may be implemented. It is noted that there are two linkages 870, 874 attached to the output joint and the butterfly extension 804 can be appended to either of the two linkages 870, 874. Both options may be implemented as part of a trial process and the best performing option selected. Then another GA is performed to refine the mechanism even further, as illustrated in FIG. 9. (As illustrated in FIG. 9, the dashed, non-circular lines compare the target curve 904 and the curve 908 of the current best candidate.) This refinement step considers all of the candidate linkage mechanisms and uses them as an initial population for a genetic algorithm which refines the linkage mechanisms both by adding and removing joints, and by moving the joints. After a finite number of iterations, the best candidate is selected and a gradient based optimization (which only moves the positions of the joints) is performed on the selected candidate.

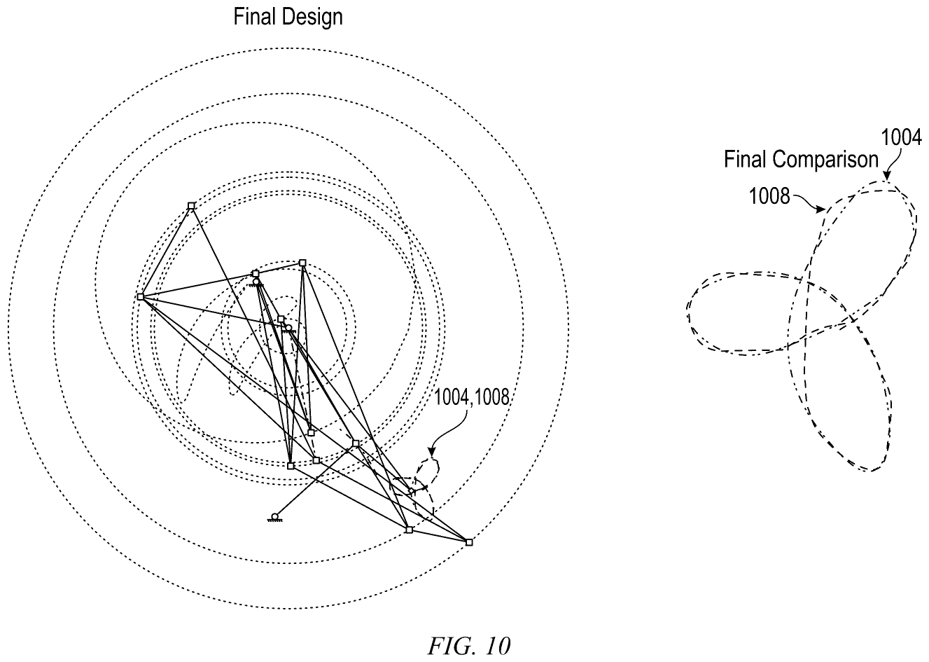

A gradient-based optimization is performed using an iterative algorithm for unconstrained nonlinear optimization to get the curve 1008 of the candidate as close to the target path as possible, as illustrated in FIG. 10. (As illustrated on the right-side of FIG. 10, the dashed lines compare (i.e., test by comparing) the target curve 1004 and the curve 1008 of the final candidate.) In one example embodiment, the gradient-based refinement is performed following the application of the second genetic algorithm using a differentiable solver by minimizing the chamfer distance between the current output and the target curves. A simple gradient descent is applied to the gradient; however, the gradient is orthogonalized with respect to the distance to locking (Σ1−cos²θᵢⱼ, where θᵢⱼ is the angle of the i^{th} linkage at time step j) in the mechanism to minimize the chances of gradient descent leading to infeasible designs.

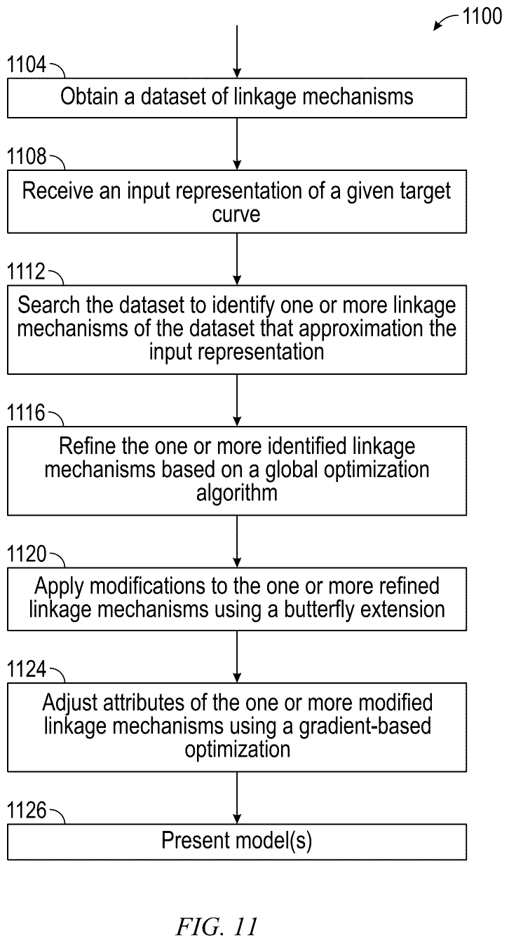

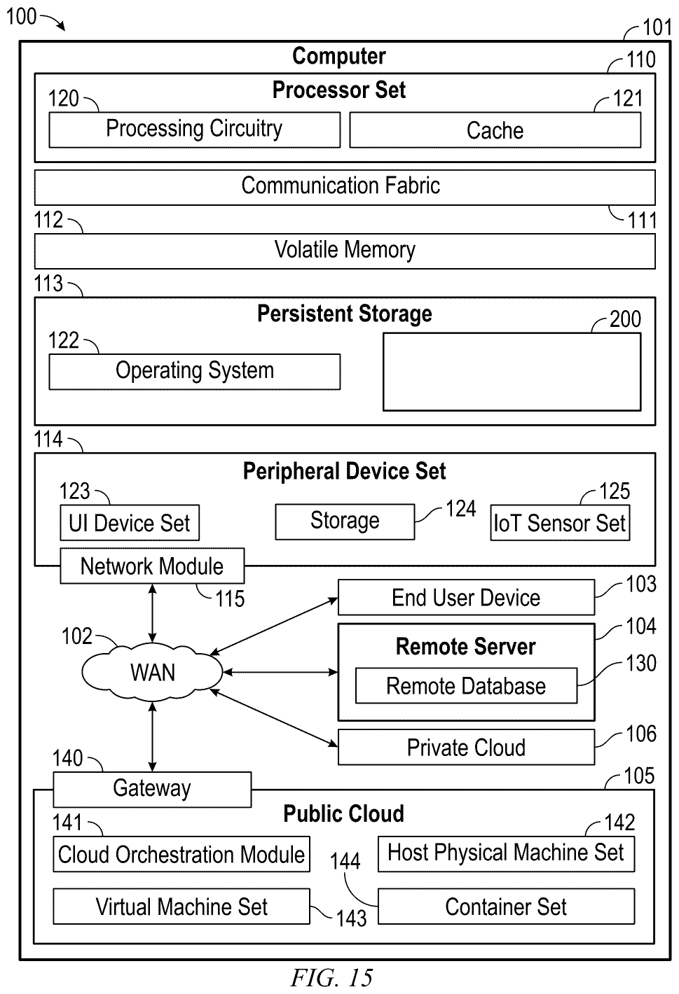

FIG. 11 is a flowchart for an example method 1100 for generating a mechanical linkage, in accordance with an example embodiment. In example embodiments, once an initial optimization is performed on a population of linkage mechanisms and the best candidate is identified, a butterfly extension 804 is attached to one of the linkages that are attached to the output joints to further improve the precision of the mechanical linkage. As noted above, there are two candidate linkages for attaching the butterfly extension 804; both options may be implemented and the best one selected. Then, a random positioning of the additional joints of the butterfly extension 804 is searched for such that the mechanism is valid (for example, a search for a mechanism that does not lock). After the addition of the butterfly extension 804, a gradient based optimization is applied to find the optimal positioning of the additional joints. At this point, the better performing butterfly extension 804 is selected and the final candidate mechanism is found. In one example embodiment, a dataset of linkage mechanisms is obtained (operation 1104). An input representation of a given target curve is received (operation 1108). The dataset is searched to identify one or more linkage mechanisms of the dataset that approximate the input representation using computational techniques (operation 1112). The one or more identified linkage mechanisms are refined based on a global optimization algorithm (operation 1116). Modifications are applied to the one or more refined linkage mechanisms using a butterfly extension 804 (operation 1120). Attributes of the one or more modified linkage mechanisms are adjusted using a gradient-based optimization (operation 1124). The so-produced one or more linkage mechanisms are presented as one or more digital three-dimensional (3D) models, respectively (operation 1126). The presentation in various embodiments includes use of a rotatable 3D model so that views of the respective linkage mechanism are rotated/rotatable. For example, a 3D graphics program automatically rotates a view on a display screen of a computer (such as computer 101 shown in FIG. 15) and/or provides user input elements which allows a user to actuate the view rotation of the digital 3D model. The presentation in various embodiments includes animation which includes a digital actuation of one or more arms of the respective linkage mechanism.

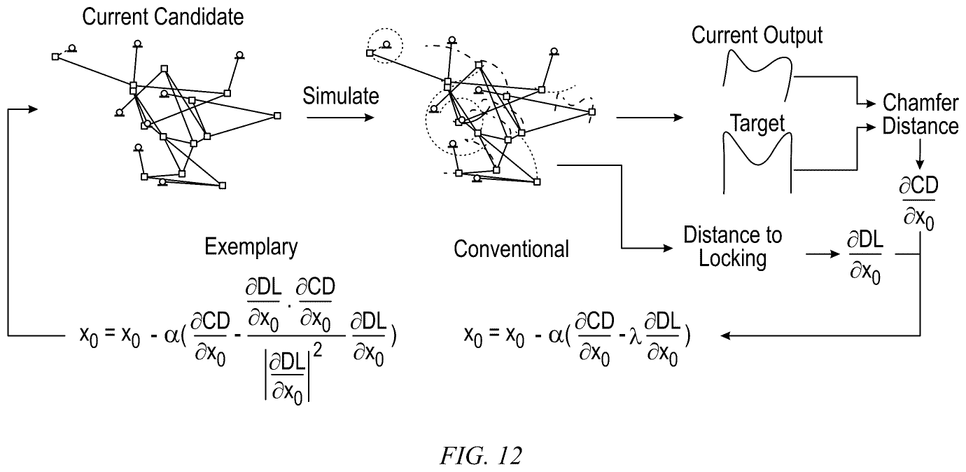

FIG. 12 illustrates a workflow for simulating a candidate linkage mechanism, in accordance with example embodiments. In one example embodiment, the candidate mechanism is simulated to determine the paths of the joints of the linkage mechanism and to determine whether the mechanism locks. A comparison of the generated curve and a given target curve is then performed based on the chamfer distance. If the mechanism does not lock and the generated curve matches the given target curve (within a given target threshold), the mechanism is accepted; otherwise, based on the results of the simulation, the joints of the mechanism may be relocated and the simulation repeated.

### Comparison to SOTA

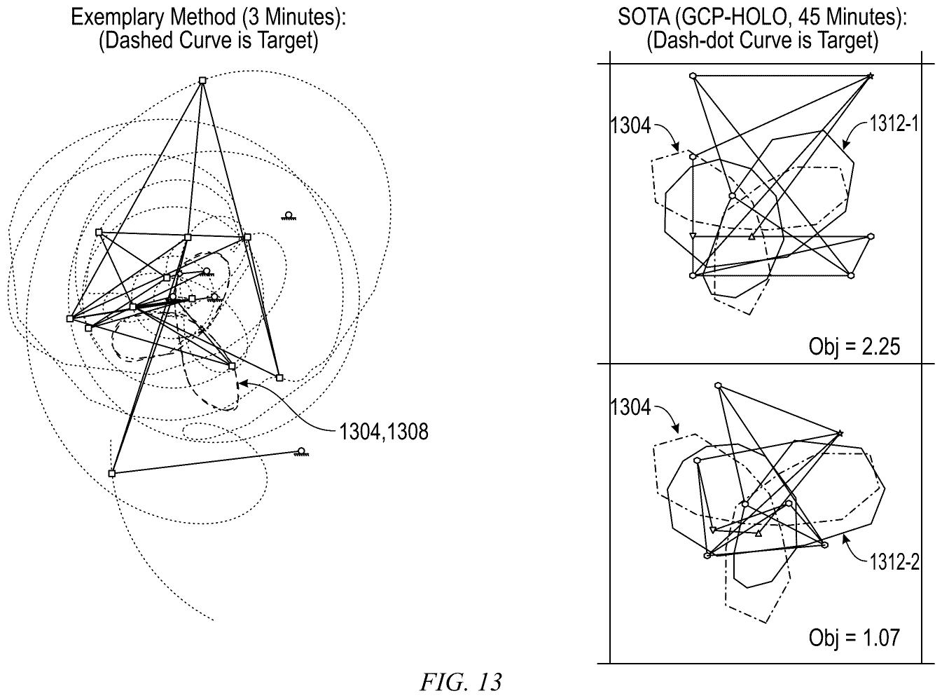

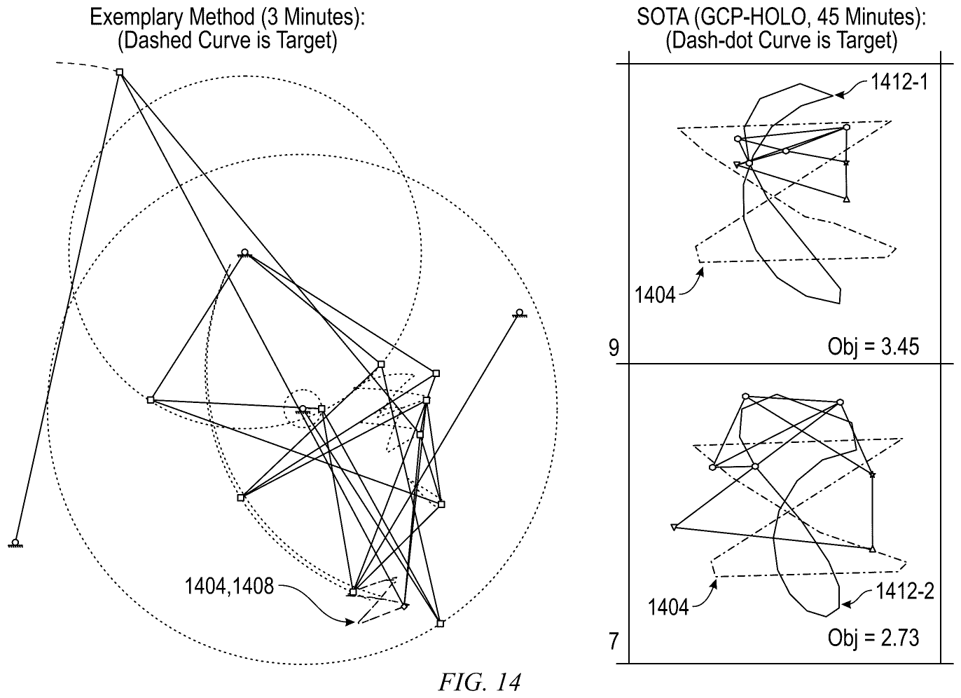

FIGS. 13-14 show a comparison of results of example embodiments with results of example state-of-the-art methods. The left-side of FIGS. 13-14 show a curve traced by a simulated candidate mechanism (generated utilizing an example embodiment) overlayed on a given target curve (dotted lines represent the paths of other joints of the linkage mechanism). The right-side of FIGS. 13-14 show the difference between the given target curve 1304, 1404 and the curves 1312-1, 1312-2, 1412-1, 1412-2 resulting from various conventional techniques. As illustrated in FIGS. 13-14, the candidate mechanism generated utilizing an example embodiment generates a curve 1308, 1408 that closely matches the given target curve 1304, 1404 whereas the curves 1312-1, 1312-2, 1412-1, 1412-2 generated by the mechanisms of the conventional techniques are substantially different than the target curve 1304, 1404.

Given the discussion thus far, it will be appreciated that, in general terms, an exemplary method, according to an aspect of the invention, includes the operations of obtaining a dataset of linkage mechanisms (operation 1104); receiving an input representation of the given target curve (operation 1108); searching the dataset to identify one or more linkage mechanisms of the dataset that approximate the input representation using computational techniques (operation 1112); refining the one or more identified linkage mechanisms based on a global optimization algorithm (operation 1116; applying modifications to the one or more refined linkage mechanisms using a butterfly extension 804 (operation 1120); and presenting the one or more modified linkage mechanisms as one or more digital three-dimensional models, respectively.

In example embodiments, the dataset of linkage mechanisms are generated using a vectorized solver approach.

In example embodiments, the searching of the dataset utilizes contrastive learning to measure a closeness between curves generated by the linkage mechanisms in the dataset and the given target curve.

In example embodiments, a second global optimization method is performed subsequent to the applying of the modifications using the butterfly extension 804.

In example embodiments, the second global optimization method is a genetic algorithm.

In example embodiments, the global optimization algorithm is initialized with top matching linkage mechanisms identified from the dataset.

In example embodiments, the linkage mechanisms in the dataset are guaranteed to have one degree of freedom and have a mobility of one.

In example embodiments, the refining of the identified linkage mechanisms is performed using a non-dominated sorting genetic algorithm.

In example embodiments, the refining of the identified linkage mechanisms based on the global optimization algorithm further comprises identifying one or more best candidates from the search using contrastive learning and initializing an optimization using a genetic algorithm.

In example embodiments, an actuator of at least one of the identified linkage mechanisms is replaced with a four-bar rocker prior to performing the refining the identified linkage mechanisms.

In example embodiments, the applying the modifications to the refined mechanisms using the butterfly extension 804 further comprises adding four new joints and corresponding linkages in two-dimensions in a butterfly shape to add eight degrees of freedom to the corresponding linkage mechanism.

In example embodiments, attributes of the one or more modified linkage mechanisms are adjusted using a gradient-based optimization.

In example embodiments, the gradient-based optimization uses a differentiable vectorized solver to minimize a chamfer distance.

In example embodiments, the gradient-based optimization is orthogonalized with respect to a distance to locking in the corresponding modified linkage mechanism.

In example embodiments, the searching of the dataset to identify the linkage mechanisms that approximate the input representation further comprises identifying one or more partial matches from results of the searching of the dataset and optimizing the partial matches.

In example embodiments, the optimizing the partial matches further comprises replacing one or more arms and links of at least one of the identified linkage mechanisms and applying an evolutionary algorithm to optimize a position of a given joint in the at least one of the identified linkage mechanisms.

In example embodiments, physical instantiation of the modified mechanical linkage are facilitated.

In example embodiments, the modified mechanical linkage is physically instantiated as a component of a suspension system for a vehicle.

In one aspect, a computer program product comprises one or more tangible computer-readable storage media and program instructions stored on at least one of the one or more tangible computer-readable storage media, the program instructions executable by a processor, the program instructions comprising obtaining a dataset of linkage mechanisms (operation 1104); receiving an input representation of the given target curve (operation 1108); searching the dataset to identify one or more linkage mechanisms of the dataset that approximate the input representation using computational techniques (operation 1112); refining the one or more identified linkage mechanisms based on a global optimization algorithm (operation 1116); applying modifications to the one or more refined linkage mechanisms using a butterfly extension 804 (operation 1120); and presenting the one or more modified linkage mechanisms as one or more digital three-dimensional models, respectively.

In one aspect, a system comprises a memory and at least one processor, coupled to the memory, and operative to perform operations comprising obtaining a dataset of linkage mechanisms (operation 1104); receiving an input representation of the given target curve (operation 1108); searching the dataset to identify one or more linkage mechanisms of the dataset that approximate the input representation using computational techniques (operation 1112); refining the one or more identified linkage mechanisms based on a global optimization algorithm (operation 1116); applying modifications to the one or more refined linkage mechanisms using a butterfly extension 804 (operation 1120); and presenting the one or more modified linkage mechanisms as one or more digital three-dimensional models, respectively.

Reference should now be had to FIG. 15. It should be noted that one or more embodiments further include carrying out or otherwise facilitating physical instantiation of the modified mechanical linkage. For example, referring to FIG. 15, plans for the linkage generated by system 200 are transmitted to a fabrication house over WAN 102. End user device 103 could be computer-controlled fabrication equipment such as one or more industrial robots, computer numerical control (CNC) drill, lathe, milling machine, grinder, router (in this context, in the sense of the machine tool not a computer router), 3D printer, or the like. The modified mechanical linkage can be physically instantiated via manual and/or computer-operated tooling and can be used in any one of a myriad of applications, such as component of a suspension system for a vehicle.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as mechanical design system 200 using aspects of the invention. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 15. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method comprising:
obtaining a dataset of linkage mechanisms;
receiving an input representation of a given target curve;
searching the dataset to identify one or more linkage mechanisms of the dataset that approximate the input representation using computational techniques;
refining the one or more identified linkage mechanisms based on a global optimization algorithm;
applying modifications to the one or more refined linkage mechanisms using a butterfly extension; and
presenting the one or more modified linkage mechanisms as one or more digital three-dimensional models, respectively.

2. The method of claim 1, further comprising generating the dataset of linkage mechanisms using a vectorized solver approach.

3. The method of claim 1, wherein the searching of the dataset utilizes contrastive learning to measure a closeness between curves generated by the linkage mechanisms in the dataset and the given target curve.

4. The method of claim 1, further comprising performing a second global optimization method subsequent to the applying of the modifications using the butterfly extension.

5. The method of claim 4, wherein the second global optimization method is a genetic algorithm.

6. The method of claim 1, wherein the global optimization algorithm is initialized with top matching linkage mechanisms identified from the dataset.

7. The method of claim 1, wherein the linkage mechanisms in the dataset are guaranteed to have one degree of freedom and have a mobility of one.

8. The method of claim 1, wherein the refining of the identified linkage mechanisms is performed using a non-dominated sorting genetic algorithm.

9. The method of claim 1, wherein the refining of the identified linkage mechanisms based on the global optimization algorithm further comprises identifying one or more best candidates from the search using contrastive learning and initializing an optimization using a genetic algorithm.

10. The method of claim 1, further comprising replacing an actuator of at least one of the identified linkage mechanisms with a four-bar rocker prior to performing the refining the identified linkage mechanisms.

11. The method of claim 1, wherein the applying the modifications to the refined mechanisms using the butterfly extension further comprises adding four new joints and corresponding linkages in two-dimensions in a butterfly shape to add eight degrees of freedom to the corresponding linkage mechanism.

12. The method of claim 1, further comprising adjusting attributes of the one or more modified linkage mechanisms using a gradient-based optimization.

13. The method of claim 12, wherein the gradient-based optimization uses a differentiable vectorized solver to minimize a chamfer distance.

14. The method of claim 12, wherein the gradient-based optimization is orthogonalized with respect to a distance to locking in the corresponding modified linkage mechanism.

15. The method of claim 1, wherein the searching of the dataset to identify the linkage mechanisms that approximate the input representation further comprises identifying one or more partial matches from results of the searching of the dataset and optimizing the partial matches.

16. The method of claim 15, wherein the optimizing the partial matches further comprises replacing one or more arms and links of at least one of the identified linkage mechanisms and applying an evolutionary algorithm to optimize a position of a given joint in the at least one of the identified linkage mechanisms.

17. The method of claim 1, further comprising facilitating physical instantiation of the modified mechanical linkage.

18. The method of claim 17, wherein the modified mechanical linkage is physically instantiated as a component of a suspension system for a vehicle.

19. A computer program product, comprising:
one or more tangible computer-readable storage media and program instructions stored on at least one of the one or more tangible computer-readable storage media, the program instructions executable by a processor, the program instructions comprising:
obtaining a dataset of linkage mechanisms;
receiving an input representation of a given target curve;
searching the dataset to identify one or more linkage mechanisms of the dataset that approximate the input representation using computational techniques;
refining the one or more identified linkage mechanisms based on a global optimization algorithm;
applying modifications to the one or more refined linkage mechanisms using a butterfly extension; and
presenting the one or more modified linkage mechanisms as one or more digital three-dimensional models, respectively.

20. A system comprising:
a memory; and
at least one processor, coupled to said memory, and operative to perform operations comprising:
obtaining a dataset of linkage mechanisms;
receiving an input representation of a given target curve;
searching the dataset to identify one or more linkage mechanisms of the dataset that approximate the input representation using computational techniques;
refining the one or more identified linkage mechanisms based on a global optimization algorithm;
applying modifications to the one or more refined linkage mechanisms using a butterfly extension; and
presenting the one or more modified linkage mechanisms as one or more digital three-dimensional models, respectively.
